(19) United States
(12) Patent Application Publication
(10) Pub. No.: US 2010/0176843 A1
(43) Pub. Date: Jul. 15, 2010

(54) METHOD AND APPARATUS FOR SETTING SAMPLING POINT OF LOW VOLTAGE DIFFERENTIAL SIGNAL TRANSMITTED BETWEEN FIELD PROGRAMMABLE GATE ARRAYS

(75) Inventor: Nam Sik CHO, Anseong-si (KR)

Correspondence Address: Jefferson IP Law, LLP, 1130 Connecticut Ave., NW, Suite 420, Washington, DC, 20036, US

(73) Assignee: SAMSUNG ELECTRONICS CO. LTD., Suwon-si (KR)

(21) Appl. No.: 12/684,744

(22) Filed: Jan. 8, 2010

(30) Foreign Application Priority Data
Jan. 9, 2009 (KR) 10-2009-0001701

(51) Int. Cl. H03K 19/003; H03K 19/0175

(52) U.S. Cl. 326/21; 326/62

(57) ABSTRACT

A method and apparatus for setting a sampling point of a low voltage differential signal transmitted between Field Programmable Gate Arrays (FPGAs) are provided. The method includes determining in which one a maintenance section or a transition section of a received signal of an initial sampling point is located in, determining a first boundary by shifting the received signal in a first direction if the initial sampling point is located in the maintenance section, determining a second boundary by shifting the first shifted signal in a second direction, and determining a sampling point for determining a sampling reference signal by shifting the second shifted signal in the first direction so that the sampling point may be located at a central position between the first and second boundaries. The method can guarantee the reliability of a data reception by preventing a signal distortion when determining a sampling point in case where the FPGA receives data at a high rate through existing input/output devices.

### PRIORITY

This application claims the benefit under 35 U.S.C. §119 to a Korean patent application filed in the Korean Intellectual Property Office on Jan. 9, 2009 and assigned Serial No. 10-2009-0001701, the entire disclosure of which is hereby incorporated reference.

### BACKGROUND OF THE INVENTION

1. Field of the Invention

The present invention relates to a method and apparatus for setting a sampling point of a signal transmitted between Field Programmable Gate Arrays (FPGAs). More particularly, the present invention relates to a method and apparatus for determining a sampling point when transmitting and receiving serial data at a high rate by using existing input/output devices between FPGAs.

2. Description of the Related Art

Based on advances in mobile communication technology, the FPGAs of a base station channel card are able to transmit and receive serial data at a rate of gigabits per second. In order to guarantee the reliability of transmission and reception of serial data at such a high rate between the FPGAs, the use of an FPGA having a transceiver dedicated for a high data rate may be considered. However, this may not only cause the production cost of the FPGA to be increased due to the adoption of the high data rate transceiver, but additionally require a separate power module to drive the high data rate transceiver. Accordingly, there remains a need to allow existing input/output devices to transmit and receive a large amount of data at a high rate between FPGAs.

One proposal to address the above demands is serial communication using a Low Voltage Differential Signaling (LVDS) of a Double Data Rate (DDR) through conventional input/output devices of the FPGA. This may require that a receiver determine a sampling point by determining bit boundaries of a received signal. However, in the case of a high DDR, or in the case where channel properties on a Printed Circuit Board (PCB) are lowered during a system integration process and thereby cause the distortion of signals, it may commit an error or failure in the determination of bit boundaries due to hardware limitations of the FPGA.

### BRIEF SUMMARY OF THE INVENTION

An aspect of the present invention is to address the above-mentioned problems and/or disadvantages and to provide at least the advantages described below.

Accordingly an aspect of the present invention is to provide a method and apparatus which may guarantee the reliability of data reception when Field Programmable Gate Arrays (FPGAs) receive data at a high rate therebetween by determining a sampling point while minimizing the distortion of received data by using existing input/output devices of the FPGA.

In accordance with an aspect of the present invention, a method for setting a sampling point of a signal between FPGAs is provided. The method includes determining in which one of a maintenance section and a transition section of a received signal an initial sampling point is located, if it is determined that the initial sampling point is located in the maintenance section, determining a first boundary by shifting the received signal in a first direction, determining a second boundary by shifting the first shifted signal in a second direction, and determining a sampling point for determining a sampling reference signal by shifting the second shifted signal in the first direction so that the sampling point is located at a central position between the first and second boundaries.

In an exemplary implementation, the method may further include, if the determined sampling point is located within a predetermined range from the first boundary or the second boundary, performing an initialization by resetting the initial sampling point and returning to the step of determining whether the initial sampling point is located in the maintenance section or the transition section.

In accordance with another aspect of the present invention, an apparatus for setting a sampling point of a signal between FPGAs is provided. The apparatus includes a section decision unit for determining in which one of a maintenance section and a transition section of a received signal an initial sampling point is located, a retardation tap control unit for shifting the received signal, and a sampling point decision unit for controlling the retardation tap control unit, for determining a first boundary by shifting the received signal in a first direction if the initial sampling point is located in the maintenance section, for determining a second boundary by shifting the first shifted signal in a second direction, and for determining a sampling point for determining a sampling reference signal by shifting the second shifted signal in the first direction so that the sampling point may be located at a central position between the first and second boundaries.

In an exemplary implementation, the apparatus may further include an initialization unit configured to initialize units used for determining a sampling point when the determined sampling point is located within a predetermined range from the first boundary or the second boundary.

Aspects of the present invention can effectively guarantee the reliability of data reception by preventing signal distortion when determining a sampling point in a case in which the FPGA receives data at a high rate through existing input/output devices. More particularly, aspects of the present invention can effectively prevent signal distortion from occurring on a Printed Circuit Board (PCB) due to a high integration of a system, and can also prevent signal distortion from occurring in the determination of a sampling point due to data variations which may be caused while retardation taps in the FPGA dynamically operate.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates connections for transmission and reception of a low voltage differential signal between Field Programmable Gate Arrays (FPGAs) in a base station channel card of a mobile communication system according to the conventional art;

FIG. 2 is a block diagram illustrating a configuration of a retardation tap control unit in a base station channel card of a mobile communication system according to the conventional art;

FIGS. 3A and 3B illustrate a method for determining bit boundaries for determining a sampling point in a base station channel card of a mobile communication system according to the conventional art;

FIG. 4 illustrates a method for determining bit boundaries for determining a sampling point in a base station channel card of a mobile communication system according to an exemplary embodiment of the present invention;

FIG. 5 illustrates an error that may occur by determination of a sampling point in a base station channel card of a mobile communication system;

FIG. 6 is a flowchart illustrating a method for determining a sampling point in a base station channel card of a mobile communication system according to an exemplary embodiment of the present invention; and

FIG. 7 is a block diagram illustrating an apparatus for determining a sampling point in a base station channel card of a mobile communication system according to an exemplary embodiment of the present invention.

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions are omitted for clarity and conciseness.

Furthermore, well known or widely used techniques, elements, structures, and processes may not be described or illustrated in detail to avoid obscuring the essence of the present invention. Although the drawings represent exemplary embodiments of the invention, the drawings are not necessarily to scale and certain features may be exaggerated or omitted in order to better illustrate and explain the present invention.

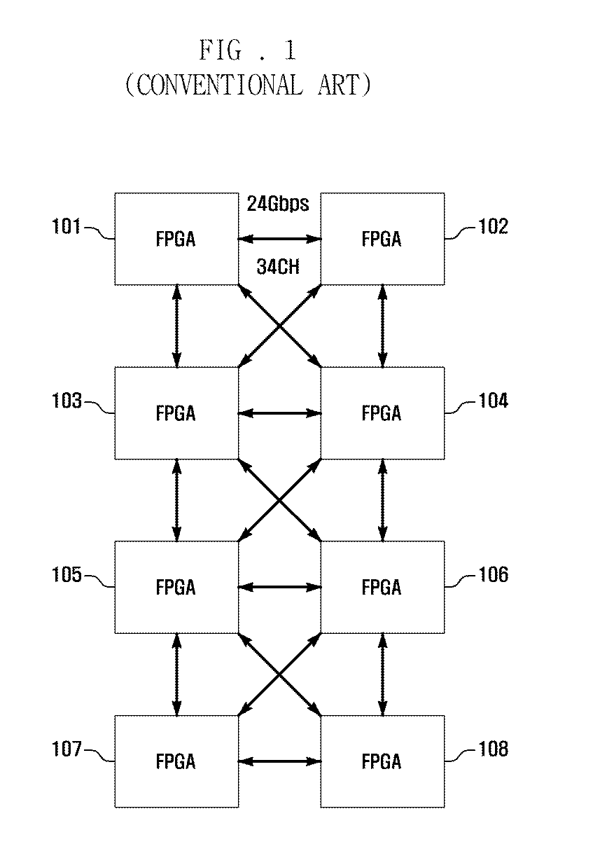

FIG. 1 illustrates connections for transmission and reception of a low voltage differential signal between Field Programmable Gate Arrays (FPGAs) in a base station channel card of a mobile communication system according to the conventional art.

Referring to FIG. 1, FPGAs 101, 102, 103, 104, 105, 106, 107 and 108 exist in the base station channel card of the mobile communication system. The respective FPGAs 101 to 108 require a data rate of about 24 Gbps therebetween. The FPGAs 101 to 108 are connected with each other in the form of a mesh to establish channels therebetween. For transmission and reception of a low voltage differential signal at a double data rate, the FPGAs 101 to 108 require thirty four channels therebetween.

If eight FPGAs 101 to 108 are deployed in the base station channel card as shown in FIG. 1, sixteen links would be needed between the FPGAs. Additionally, since each channel for transmission and reception of a low voltage differential signal has a positive path and a negative path, one thousand eighty eight input/output ports are needed in order to compose thirty four channels (i.e., 34 channels×16 links×2 paths=1088 ports). Unfortunately, if an error in determination of a sampling point occurs at a path of even only one of such input/output ports, the stability in the restoration of a received signal would be considerably lowered.

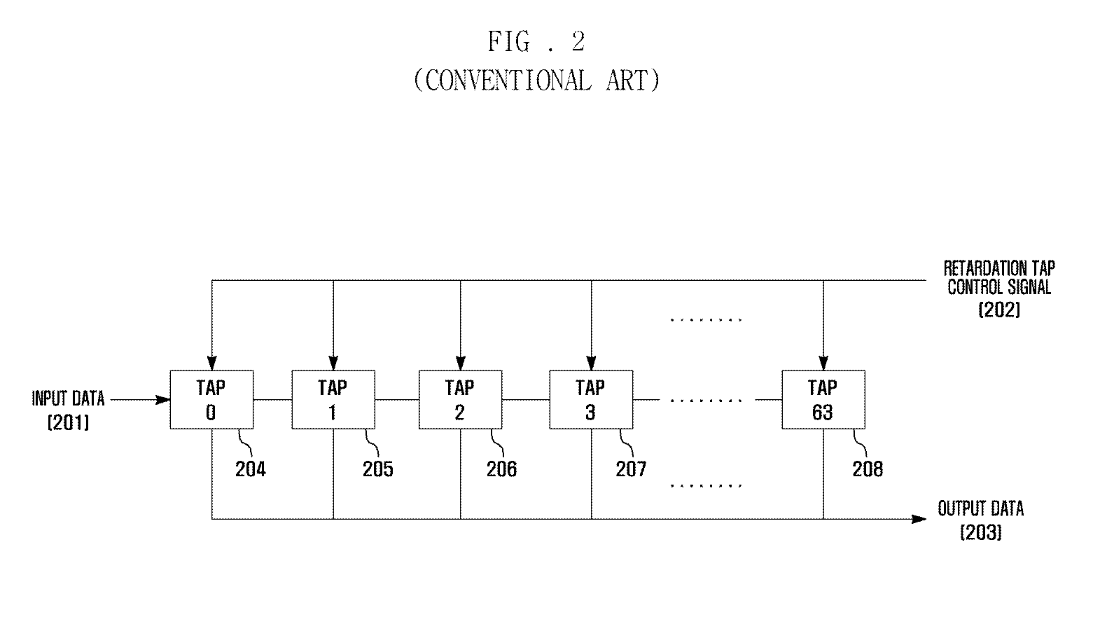

FIG. 2 is a block diagram illustrating a configuration of a retardation tap control unit in a base station channel card of a mobile communication system according to the conventional art.

Referring to FIG. 2, the retardation tap control unit in an FPGA is composed of sixty four retardation taps 204, 205, 206, 207 and 208 for retarding input data 201. Retardation tap control signals 202, which are applied to the respective retardation taps from 204 to 208 may increase or decrease the number of taps through which the input data 201 passes. This generates output data 203 leftward shifted or rightward shifted from the input data 201.

Generally a signal retarding technique using the retardation tap control unit is used to regulate a sampling point. Specifically, left and right boundaries are determined from data one bit of an input signal. Then synchronism is obtained by creating a sampling reference signal so that a sampling point may be located at a central position between the left and right boundaries.

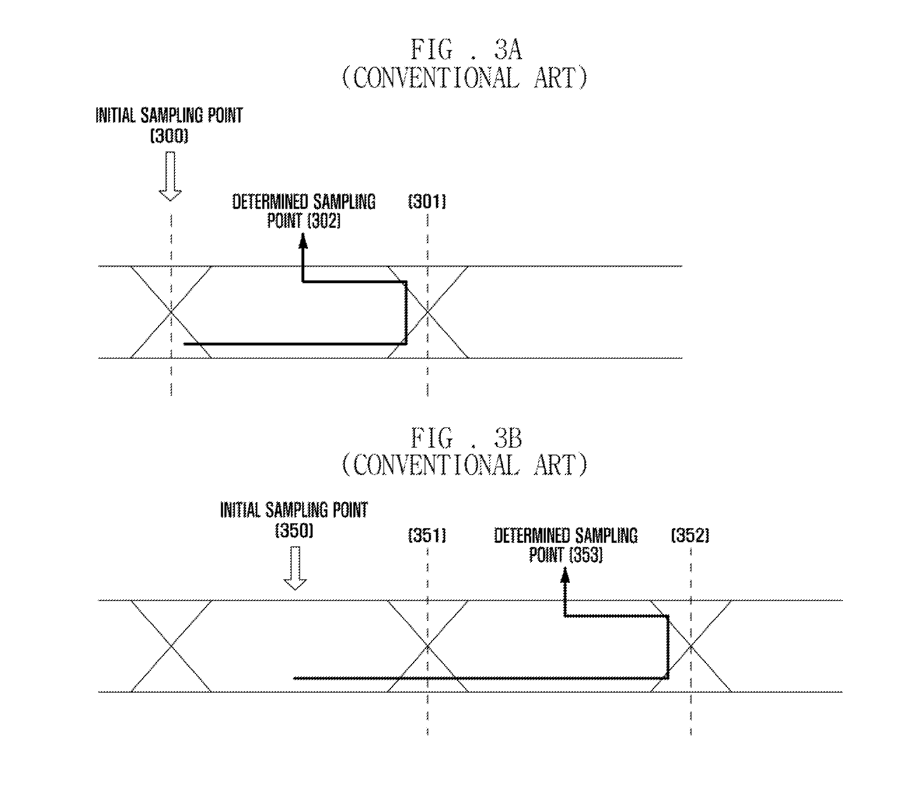

FIGS. 3A and 3B illustrate a method for determining bit boundaries for determining a sampling point in a base station channel card of a mobile communication system according to the conventional art.

Referring to FIG. 3A, an initial sampling point 300, located in a data transition section, is illustrated. In this case, a left boundary is determined as the transition section in which the initial sampling point 300 is located. Then the retardation tap control unit performs a rightward shift of a signal to the next transition section, and a right boundary 301 is determined as the next transition section. Thereafter a sampling reference signal is created so that a sampling point 302 may be located at a central position between the left and right boundaries 300 and 301, and thereby synchronism is obtained.

Referring to FIG. 3B, an initial sampling point 350, located in a maintenance section where no data transition happens, is illustrated. In this case, the retardation tap control unit performs a first rightward shift of a signal to the first transition section, and a left boundary 351 is determined as that transition section. Then a second rightward shift is performed to the next transition section, and a right boundary 352 is determined as that transition section. Thereafter a sampling reference signal is created so that a sampling point 353 may be located at a central position between the left and right boundaries 351 and 352, and thereby synchronism is obtained.

Normally, a Printed Circuit Board (PCB) is designed to minimize interference between channels for transmission and reception of a low voltage differential signal. Therefore, in case of data transmission using many channels, there is a high probability that a sampling point is deviated. Additionally, many numbers of retardation taps used for a continuous rightward shift may cause noise in high rate data signals, thus lowering a data rate.

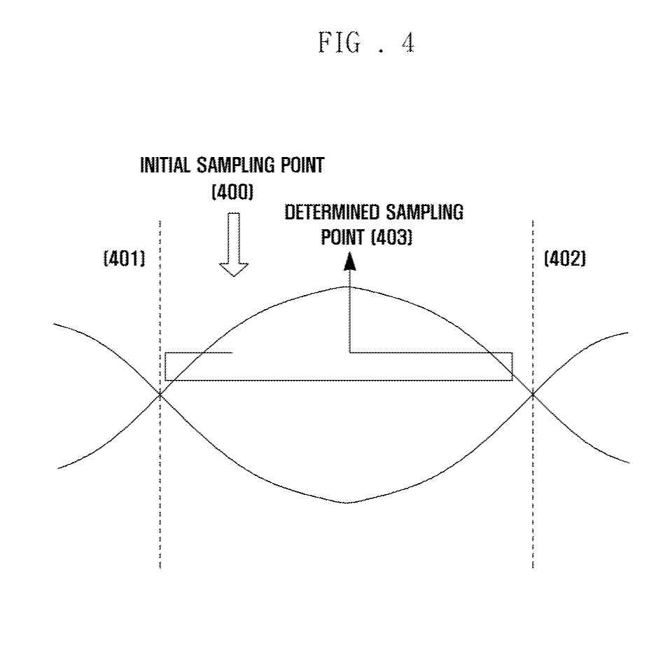

FIG. 4 illustrates a method for determining bit boundaries for determining a sampling point in a base station channel card of a mobile communication system according to an exemplary embodiment of the present invention.

Referring to FIG. 4, a method is illustrated to address the above discussed problems of FIG. 3B. That is, the exemplary method of FIG. 4 addresses a problem of deviation of a sampling point, and a problem of noise in high rate data signals. More specifically, when an initial sampling point 400 is located in a maintenance section where no data transition happens, the signal is shifted in a first direction by control of the retardation tap until a first boundary 401 is determined. In the illustrated example, the first shift is in the leftward direction. Moreover, the first boundary 401 is the transition section. Then, a second shift is performed in a second direction and thereby a second boundary 402 is determined. In the illustrated example, the second shift is in the rightward direction. Moreover, the second boundary 402 is the transition section. Thereafter a sampling reference signal is created so that a sampling point 403 may be located at a central position between the left and right boundaries 401 and 402, and thereby synchronism is obtained.

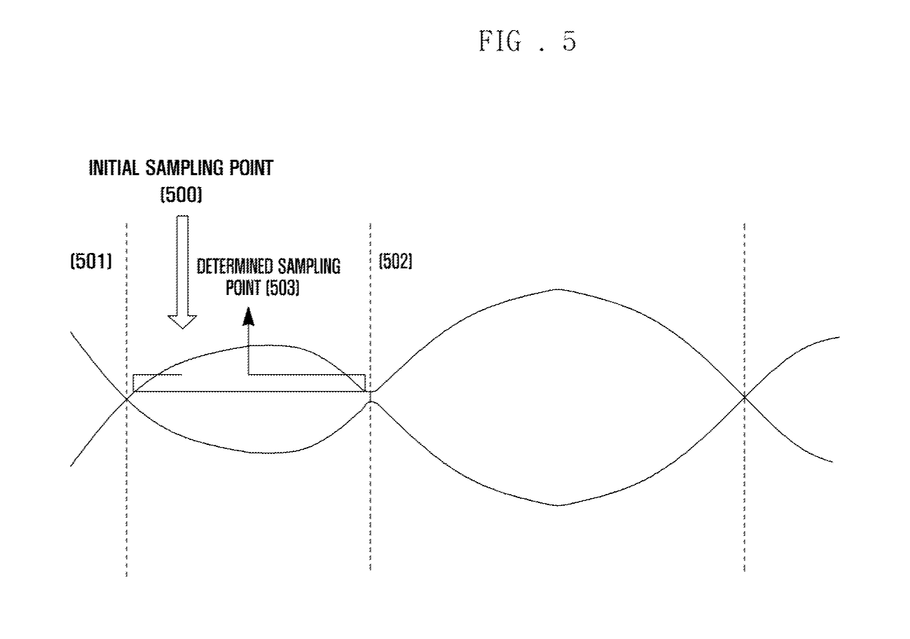

FIG. 5 illustrates an error that may occur by determination of a sampling point in a base station channel card of a mobile communication system.

Referring to FIG. 5, if the data eye of a transmitted signal is closed or distorted due to degradation of signal properties in system integration, a sampling point may be wrongly determined as being located near a front position rather than at the central position of the data eye. For example, if a data signal is transmitted at a double data rate of 1 Gbps, the data rate of a signal transmitted through input/output ports for transmission and reception of a single low voltage differential signal is 1000 Mbit/s. Therefore, transmission of one bit needs 1.0 ns, and the time delayed when passing through one tap is about 79 ps. If the determination of a sampling point is normal, a sampling point 503 may be determined, for example by leftward shifting through control of the retardation tap until a left boundary 501 is determined and rightward shifting until a right boundary 502 is determined, in a section rightward shifted through six or seven taps from the left boundary 501. However, if the data eye of a data signal is closed or distorted, a sampling point may be wrongly determined after being rightward shifted through only one or two taps from a left boundary.

Accordingly, an exemplary method for determining a sampling point in may include determining a half eye value (i.e., a distance between the sampling point and the left boundary 501) after determining the sampling point. If the detected half eye value does not exceed a predetermined value, in other words, if a sampling point is located more leftward than a section rightward shifted through six or seven taps from a left boundary, the method of this invention may initialize a receiver and change the location of an initial sampling point 500.

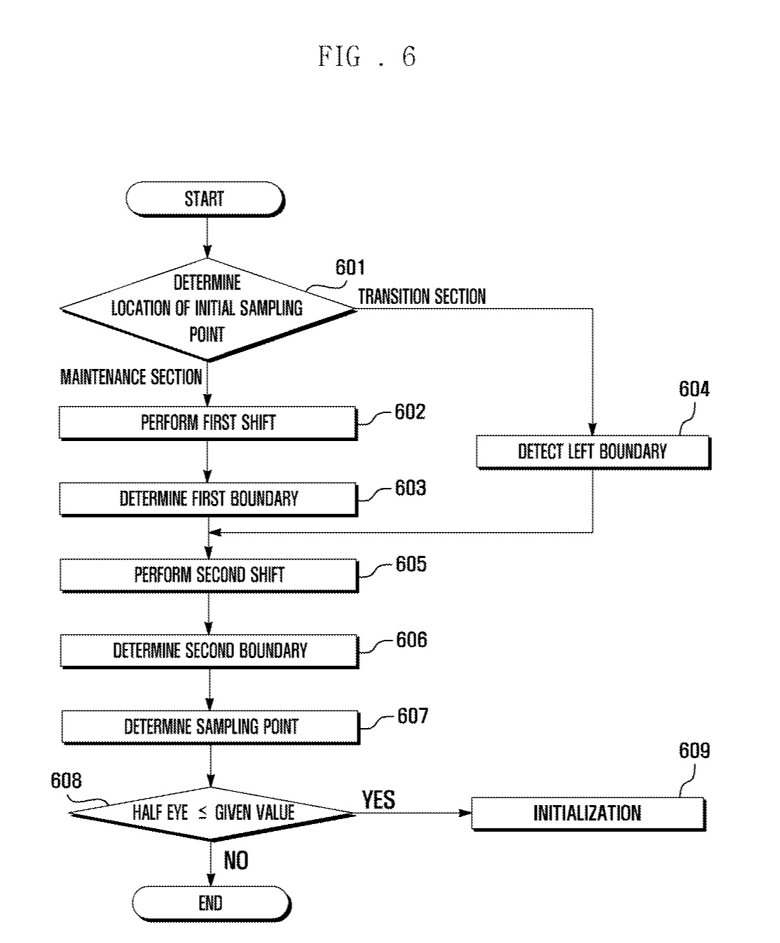

FIG. 6 is a flowchart illustrating a method for determining a sampling point in a base station channel card of a mobile communication system according to an exemplary embodiment of the present invention.

Referring to FIG. 6, in step 601 the channel card determines in which one of a maintenance section and a transition section of a received signal an initial sampling point is located. If it is determined that the initial sampling point is located in a maintenance section, the channel card leftward shifts the received signal in step 602 and determines a left boundary of the signal in step 603. On the other hand, if it is determined that the initial sampling point is located in a transition section, the channel card determines a left boundary of the received signal in the transition section in step 604.

There may occur an undesired change in an output signal leftward shifted in the retardation tap control unit. This may be caused by damage of data as an input signal passes through the retardation taps. Therefore, if it is determined that a leftward shifted signal is distorted, the channel card restores the leftward shifted signal to a state before shifting and performs step 603 again. In this case the number of retardation taps through which an input signal passes should be reset to a specific number before distortion happens. If the number of retardation taps remains unchanged, this may also cause an error of a signal.

After determination of the left boundary in step 603, the channel card rightward shifts the signal in step 605 and determines a right boundary of that signal in step 606. In the step 605, if it is determined that a rightward shifted signal is distorted, the channel card restores the rightward shifted signal to a state before shifting and perform step 605 again. In this case, the number of retardation taps through which an input signal passes should be reset to a specific number before distortion happens.

Next, the channel card leftward shifts the signal so that a sampling point may be located at a central position between the left and right boundaries, and thereby determines a sampling reference signal in step 607. Thereafter, the channel card determines whether a half eye value does not exceed a predetermined value in step 608. In an exemplary implementation, the channel card determines whether a half eye value exceeds a predetermined value by determining a distance between the sampling point and the left boundary. In other words, it is determined whether the sampling point is located within a predetermined range from the left boundary due to the data eye of the signal being closed or distorted. If the half eye value does not exceed the predetermined value, the sampling point may be wrongly determined near a front position rather than at a central position of the data eye. If it is determined in step 608 that the half eye value does not exceed the predetermined value, the channel card initializes a receiver and then changes the location of an initial sampling point in step 609. Otherwise, if it is determined in step 608 that the half eye value does exceed the predetermined value, the procedure is ended.

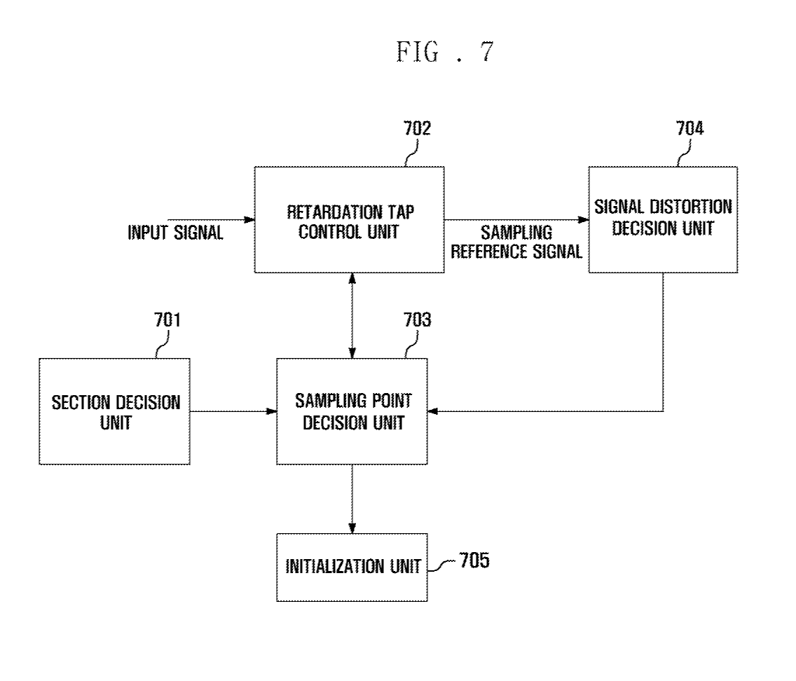

FIG. 7 is a block diagram illustrating an apparatus for determining a sampling point in a base station channel card of a mobile communication system according to an exemplary embodiment of the present invention.

Referring to FIG. 7, the apparatus for determining a sampling point in a base station channel card of a mobile communication system includes a section decision unit 701, a retardation tap control unit 702, a sampling point decision unit 703, a signal distortion decision unit 704, and an initialization unit 705.

The section decision unit 701 determines in which one of a maintenance section and a transition section of a received signal an initial sampling point is located.

In an exemplary implementation, the retardation tap control unit 702 has a configuration as illustrated in FIG. 2 and performs a leftward or rightward shift on a received signal.

The sampling point decision unit 703 controls the retardation tap control unit 702. If an initial sampling point is located in the maintenance section, the sampling point decision unit 703 leftward shifts the received signal and then determines a left boundary of the signal. If an initial sampling point is located in the transition section, the sampling point decision unit 703 determines a left boundary of the signal in the transition section. Additionally, the sampling point decision unit 703 rightward shifts the signal with the left boundary determined and then determines a right boundary of that signal. Also, the sampling point decision unit 703 determines a sampling point in order to determine a sampling reference signal by leftward shifting the rightward shifted signal so that the sampling point may be located at a central position between the left and right boundaries.

The signal distortion decision unit 704 determines whether there is distortion in the leftward shifted or rightward shifted signal. If there is distortion, the signal distortion decision unit 704 restores the leftward shifted or rightward shifted signal to a state before shifting.

The initialization unit 705 initializes units used for determining a sampling point when the determined sampling point is located within a predetermined range from the left boundary.

While this invention has been shown and described with reference to certain exemplary embodiments thereof, it will be understood by those of skill in the art that various changes in form and details may be made therein without departing from the spirit and scope of the invention as defined by the appended claims and their equivalents.

What is claimed is:

1. A method for setting a sampling point of a signal between field programmable gate arrays, the method comprising:
determining in which one of a maintenance section and a transition section of a received signal an initial sampling point is located;
if it is determined that the initial sampling point is located in the maintenance section, determining a first boundary by shifting the received signal in a first direction;
determining a second boundary by shifting the first shifted signal in a second direction; and
determining a sampling point for determining a sampling reference signal by shifting the second shifted signal in the first direction so that the sampling point is located at a central position between the first and second boundaries.

2. The method of claim 1, further comprising:
if it is determined that the initial sampling point is located in the transition section, determining the first boundary as the transition section.

3. The method of claim 1, wherein the determining of the first boundary by shifting the received signal in the first direction comprises shifting the received signal to the transition section.

4. The method of claim 1, wherein the determining of the second boundary by shifting the first shifted signal in the second direction comprises shifting the first shifted signal to another transition section.

5. The method of claim 1, wherein the first shift comprises a leftward shift, the second shift comprises a rightward shift, the first boundary is a left boundary and the second boundary is a right boundary.

6. The method of claim 1, further comprising:
if there is a distortion in the first shifted signal, restoring the first shifted signal to a state before the first shift and re-determining the first boundary.

7. The method of claim 1, further comprising:
if there is a distortion in the second shifted signal, restoring the second shifted signal to a state before the second shift and re-determining the second boundary.

8. The method of claim 1, further comprising:
if the determined sampling point is located within a predetermined range from at least one of the first boundary and the second boundary, performing an initialization by resetting the initial sampling point and returning to the step of determining in which one of the maintenance section and the transition section the initial sampling point is located.

9. An apparatus for setting a sampling point of a signal between field programmable gate arrays, the apparatus comprising:
a section decision unit for determining in which one of a maintenance section and a transition section of a received signal an initial sampling point is located;
a retardation tap control unit for shifting for the received signal; and
a sampling point decision unit for controlling the retardation tap control unit, for determining a first boundary by shifting the received signal in a first direction if the initial sampling point is located in the maintenance section, for determining a second boundary by shifting the first shifted signal in a second direction, and determining a sampling point for determining a sampling reference signal, by shifting the second shifted signal in the first direction so that the sampling point is located at a central position between the first and second boundaries.

10. The apparatus of claim 9, wherein the sampling point decision unit is further configured to determine the first boundary in the transition section if the initial sampling point is located in the transition section.

11. The apparatus of claim 9, wherein the sampling point decision unit determines the first boundary by shifting the received signal to the transition section.

12. The apparatus of claim 9, wherein the sampling point decision unit determines the second boundary by shifting the first shifted signal to another transition section.

13. The apparatus of claim 9, wherein the first shift comprises a leftward shift, the second shift comprises a rightward shift, the first boundary is a left boundary and the second boundary is a right boundary.

14. The apparatus of claim 9, further comprising:
a signal distortion decision unit for determining whether there is distortion in the first shifted signal or the second shifted signal, and, if it is determined that there is distortion, to restore the first shifted signal or the second shifted signal to a state before being shifted.

15. The apparatus of claim 9, further comprising:
an initialization unit for initializing units used for determining a sampling point when the determined sampling point is located within a predetermined range from the first boundary or the second boundary.
